(19) United States
(12) Patent Application Publication
(10) Pub. No.: US 2025/0374769 A1
(43) Pub. Date: Dec. 4, 2025

(54) DISPLAY DEVICE AND MANUFACTURING METHOD OF THE SAME

(71) Applicant: Japan Display Inc., Tokyo (JP)

(72) Inventor: Kaichi FUKUDA, Tokyo (JP)

(73) Assignee: Japan Display Inc., Tokyo (JP)

(21) Appl. No.: 19/220,178

(22) Filed: May 28, 2025

(30) Foreign Application Priority Data
May 29, 2024 (JP) 2024-087136

(51) Int. Cl. H10K 59/122; H10K 59/12

(52) U.S. Cl. CPC H10K 59/122; H10K 59/1201

(57) ABSTRACT

According to one embodiment, a display device includes an organic insulating layer, a lower electrode above the organic insulating layer, an inorganic insulating layer provided between the organic insulating layer and the lower electrode, a rib layer covering an end portion of the lower electrode and including a pixel aperture overlapping with the lower electrode, an organic layer covering the lower electrode through the pixel aperture and emitting light in accordance with application of a voltage, and an upper electrode covering the organic layer. Furthermore, an end portion of the inorganic insulating layer protrudes from an end portion of the lower electrode.

### CROSS-REFERENCE TO RELATED APPLICATION

This application is based upon and claims the benefit of priority from Japanese Patent Application No. 2024-087136, filed May 29, 2024, the entire contents of which are incorporated herein by reference.

### FIELD

Embodiments described herein relate generally to a display device and a manufacturing method of the same.

### BACKGROUND

Recently, display devices to which an organic light emitting diode (OLED) is applied as a display element have been put into practical use. In this type of display devices, a technique which can improve the yield is required.

### BRIEF DESCRIPTION OF THE DRAWINGS

FIG. 1 is a diagram showing a configuration example of a display device according to a first embodiment.

FIG. 2 is a schematic plan view showing an example of a layout of subpixels according to the first embodiment.

FIG. 3 is a schematic cross-sectional view showing the display device along III-III line in FIG. 2.

FIG. 4 is a schematic cross-sectional view showing the display device along IV-IV line in FIG. 2.

FIG. 5 is a schematic cross-sectional view showing the display device along V-V line in FIG. 2.

FIG. 6 is a schematic cross-sectional view showing another structure which can be applied to a vicinity of a contact hole.

FIG. 7 is a schematic cross-sectional view showing yet another structure which can be applied to the vicinity of the contact hole.

FIG. 8 is a flowchart showing an example of a manufacturing method of the display device according to the first embodiment.

FIG. 9A is a schematic cross-sectional view showing a manufacturing process of the display device.

FIG. 9B is a schematic cross-sectional view showing a process following FIG. 9A.

FIG. 9C is a schematic cross-sectional view showing a process following FIG. 9B.

FIG. 9D is a schematic cross-sectional view showing a process following FIG. 9C.

FIG. 9E is a schematic cross-sectional view showing a process following FIG. 9D.

FIG. 9F is a schematic cross-sectional view showing a process following FIG. 9E.

FIG. 9G is a schematic cross-sectional view showing a process following FIG. 9F.

FIG. 10A is a schematic cross-sectional view showing a process following FIG. 9G.

FIG. 10B is a schematic cross-sectional view showing a process following FIG. 10A.

FIG. 10C is a schematic cross-sectional view showing a process following FIG. 10B.

FIG. 10D is a schematic cross-sectional view showing a process following FIG. 10C.

FIG. 10E is a schematic cross-sectional view showing a process following FIG. 10D.

FIG. 10F is a schematic cross-sectional view showing a process following FIG. 10E.

FIG. 11 is a diagram for explaining an example of effects obtained from the first embodiment.

FIG. 12 is a schematic plan view showing an example of a layout of subpixels according to a second embodiment.

FIG. 13 is a schematic cross-sectional view showing the display device along XIII-XIII line in FIG. 12.

### DETAILED DESCRIPTION

In general, according to one embodiment, there is provided a display device comprising: an organic insulating layer formed of an organic insulating material; a lower electrode provided above the organic insulating layer; an inorganic insulating layer formed of an inorganic insulating material and provided between the organic insulating layer and the lower electrode; a rib layer covering an end portion of the lower electrode and including a pixel aperture overlapping with the lower electrode; an organic layer covering the lower electrode through the pixel aperture and emitting light in accordance with application of a voltage; and an upper electrode covering the organic layer. Furthermore, an end portion of the inorganic insulating layer protrudes from an end portion of the lower electrode.

According to another embodiment, there is provided a display device manufacturing method comprising: forming an organic insulating layer of an organic insulating material; forming above the organic insulating layer a lower electrode, and an inorganic insulating layer which is formed of an inorganic insulating material, which is located between the organic insulating layer and the lower electrode, and which has an end portion protruding from an end portion of the lower electrode; forming a rib layer which covers an end portion of the lower electrode and which includes a pixel aperture overlapping with the lower electrode; forming an organic layer which covers the lower electrode through the pixel aperture and which emits light in accordance with application of a voltage; and forming an upper electrode covering the organic layer.

According to the configuration of the display device and the display device manufacturing method, the yield of the display device can be improved.

Several embodiments will be described hereinafter with reference to the accompanying drawings.

The disclosure is merely an example, and proper changes within the spirit of the invention, which are easily conceivable by a person of ordinary skill in the art, are included in the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

Incidentally, in the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. In addition, when various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

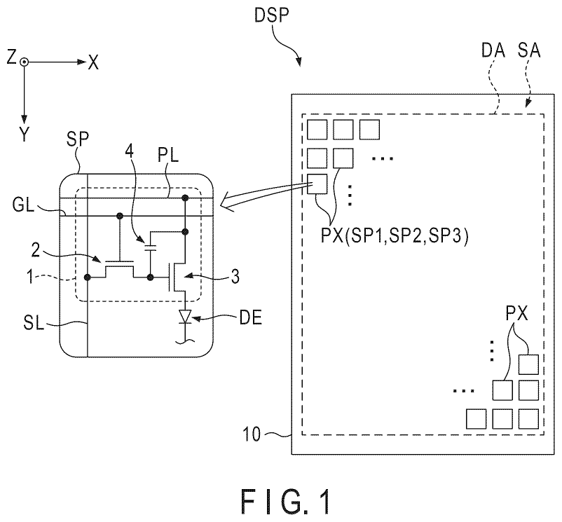

FIG. 1 is a diagram showing a configuration example of a display device DSP according to a first embodiment. The display device DSP comprises an insulating substrate 10. The substrate 10 has a display area DA where an image is displayed, and a surrounding area SA around the display area DA. The substrate 10 may be glass or a resinous film having flexibility.

In the embodiment, the substrate 10 is rectangular as seen in plan view. However, the shape of the substrate 10 in plan view is not limited to a rectangle and may be another shape such as a square, a circle or an oval.

The display area DA comprises a plurality of pixels PX arrayed in matrix in the X-direction and the Y-direction. Each pixel PX includes a plurality of subpixels SP which display different colors. In the present embodiment, it is assumed that the pixel PX includes a blue subpixel SP1 (first subpixel), a green subpixel SP2 (second subpixel), and a red subpixel SP3 (third subpixel). However, the pixel PX may include a subpixel SP which exhibits another color such as white in addition to subpixels SP1, SP2, and SP3 or instead of one of subpixels SP1, SP2, and SP3.

Each subpixel SP comprises a pixel circuit 1 and a display element DE driven by the pixel circuit 1. The pixel circuit 1 comprises a pixel switch 2, a drive transistor 3, and a capacitor 4. Each of the pixel switch 2 and the drive transistor 3 is, for example, a switching element consisting of a thin-film transistor.

A plurality of scanning lines GL that supply a scanning signal to the pixel circuit 1 of each subpixel SP, a plurality of signal lines SL that supply a video signal to the pixel circuit 1 of each subpixel

SP, and a plurality of power lines PL are provided in the display area DA. In the example of FIG. 1, the scanning lines GL and the power lines PL extend in the X-direction, and the signal lines SL extend in the Y-direction.

The gate electrode of the pixel switch 2 is connected to a scanning line GL. The source electrode of the pixel switch 2 is connected to the signal line SL. The drain electrode of the pixel switch 2 is connected to the gate electrode of the drive transistor 3 and the capacitor 4. The source electrode of the drive transistor 3 is connected to the power line PL and the capacitor 4. The drain electrode of the drive transistor 3 is connected to the display element DE.

Incidentally, the configuration of the pixel circuit 1 is not limited to the example shown in the figure. For example, the pixel circuit 1 may comprise more thin-film transistors and more capacitors.

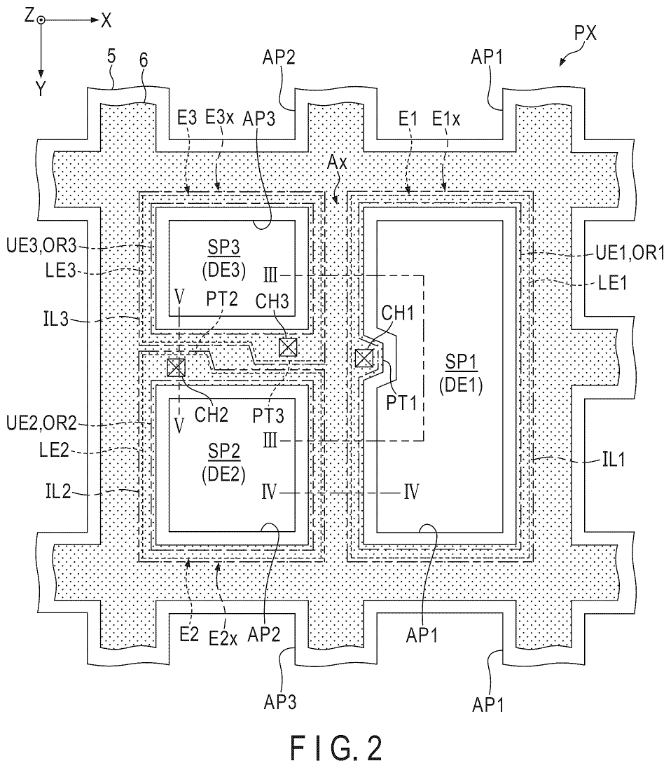

FIG. 2 is a schematic plan view showing an example of the layout of subpixels SP1, SP2, and SP3. In the example of FIG. 2, each of the subpixels SP2 and SP3 is adjacent to the subpixel SP1 in the X-direction. Furthermore, the subpixels SP2 and SP3 are arranged in the Y-direction.

When the subpixels SP1, SP2, and SP3 are provided in this layout, a column in which the subpixels SP2 and SP3 are alternately provided in the Y-direction and a column in which a plurality of subpixels SP1 are repeatedly provided in the Y-direction are formed in the display area DA. These columns are alternately arranged in the X-direction. Incidentally, the layout of the subpixels SP1, SP2, and SP3 is not limited to the example of FIG. 2.

A rib layer 5 is provided in the display area DA. The rib layer 5 includes pixel apertures AP1, AP2, and AP3 in the subpixels SP1, SP2, and SP3, respectively. In the example of FIG. 2, the pixel aperture AP1 is larger than the pixel aperture AP2, and the pixel aperture AP2 is larger than the pixel aperture AP3. In other words, among subpixels SP1, SP2, and SP3, the aperture ratio of the subpixel SP1 is the greatest, and the aperture ratio of the subpixel SP3 is the smallest. Incidentally, the size of the pixel aperture AP1, AP2, and AP3 is not limited to this example. For example, at least two of the pixel apertures AP1, AP2, and AP3 may have the same size.

The subpixel SP1 comprises a lower electrode LE1, an upper electrode UE1, and an organic layer OR1 each overlapping with the pixel aperture AP1. The subpixel SP2 comprises a lower electrode LE2, an upper electrode UE2, and an organic layer OR2 each overlapping with the pixel aperture AP2. The subpixel SP3 comprises a lower electrode LE3, an upper electrode UE3, and an organic layer OR3 each overlapping with the pixel aperture AP3.

The portions of the lower electrode LE1, the upper electrode UE1, and the organic layer OR1, which overlap with the pixel aperture AP1, constitute the display element DE1 of the subpixel SP1. The portions of the lower electrode LE2, the upper electrode UE2, and the organic layer OR2, which overlap with the pixel aperture AP2, constitute the display element DE2 of the subpixel SP2. The portions of the lower electrode LE3, the upper electrode UE3, and the organic layer OR3, which overlap with the pixel aperture AP3, constitute the display element DE3 of the subpixel SP3. Each of the display elements DE1, DE2, and DE3 may further include a cap layer as described later. The rib layer 5 surrounds each of these display elements DE1, DE2, and DE3.

A partition 6 is provided in the display area DA. The partition 6 is located above the rib layer 5 and overlaps with the rib layer 5 as a whole. In the example of FIG. 2, the partition 6 has a planar shape similar to that of the rib layer 5. In other words, the partition 6 includes an aperture in each of the subpixels SP1, SP2, and SP3. From another viewpoint, each of the rib layer 5 and the partition 6 has a grating shape as seen in plan view, and surrounds each of the display elements DE1, DE2, and DE3. The partition 6 functions as lines which supply a common voltage to the upper electrodes UE1, UE2, and UE3.

In the present embodiment, inorganic insulating layers IL1, IL2, and IL3 are provided under the lower electrodes LE1, LE2, and LE3, respectively. In the example of FIG. 2, the inorganic insulating layers IL1, IL2, and IL3 are spaced apart from each other.

The inorganic insulating layers IL1, IL2, and IL3 have outer shapes slightly greater than the lower electrodes LE1, LE2, and LE3, respectively. In other words, an end portion E1x of the inorganic insulating layer IL1 protrudes from an end portion E1 of the lower electrode LE1 in entire periphery. In addition, an end portion E2x of the inorganic insulating layer IL2 protrudes from an end portion E2 of the lower electrode LE2 in entire periphery. An end portion E3x of the inorganic insulating layer IL3 protrudes from an end portion E3 of the lower electrode LE3 in entire periphery.

Incidentally, the shapes of the inorganic insulating layers IL1, IL2, and IL3 are not limited to the example of FIG. 2. For example, parts of the inorganic insulating layers IL1, IL2, and IL3 may be connected to one another. Alternatively, part of each of the end portions E1x, E2x, and E3x may overlap with the lower electrodes LEI, LE2, and LE3.

The lower electrodes LE1, LE2, and LE3 are connected to the pixel circuits 1 (more specifically, the drain electrodes of the drive transistors 3 shown in FIG. 1) of the subpixels SP1, SP2, and SP3 through contact holes CH1, CH2, and CH3 provided in an organic insulating layer 12 to be described later, respectively. Each of the contact holes CH1, CH2, and CH3 overlaps with the rib layer 5 and the partition 6.

In the example of FIG. 2, the partition 6 has a protrusion PT1 which protrudes toward the pixel aperture AP1. The contact hole CH1 overlaps with the protrusion PT1. In addition, the lower electrode LE2 has a protrusion PT2 which protrudes toward the lower electrode LE3. Furthermore, the lower electrode LE3 has a protrusion PT3 which protrudes toward the lower electrode LE2. The contact holes CH2 and CH3 overlap with these protrusions PT2 and PT3, respectively.

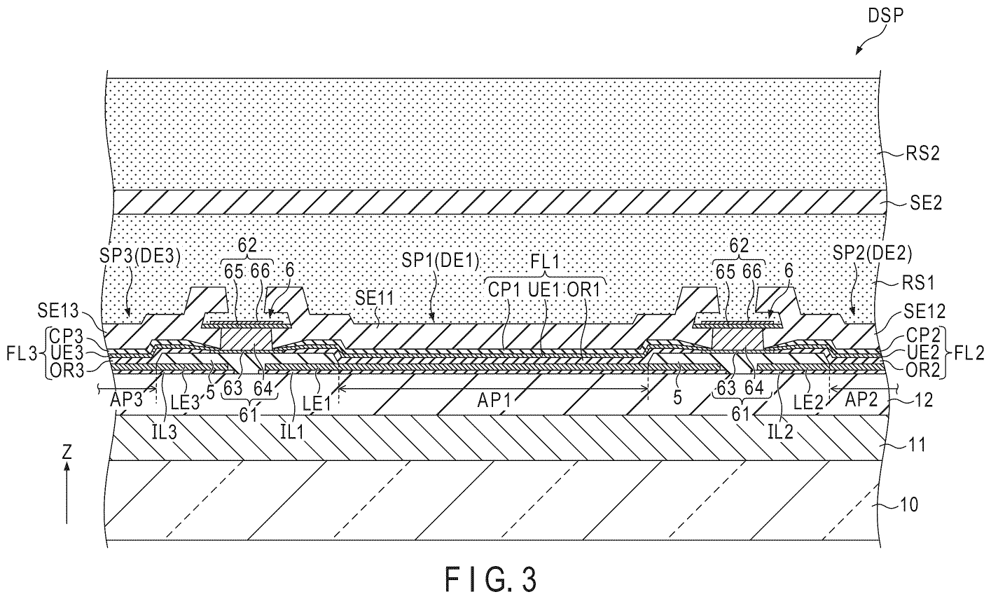

FIG. 3 is the schematic cross-sectional view showing the display device DSP along the III-III line in FIG. 2. A circuit layer 11 is provided on the substrate 10 described above. The circuit layer 11 includes various circuits and lines such as the pixel circuit 1, scanning line GL, signal line SL and power line PL shown in FIG. 1. The circuit layer 11 is covered with an organic insulating layer 12. The organic insulating layer 12 functions as a planarization film which planarizes the irregularities formed by the circuit layer 11.

The inorganic insulating layers IL1, IL2, and IL3 are provided on the organic insulating layer 12. The lower electrodes LE1, LE2, and LE3 are provided on the inorganic insulating layers IL1, IL2, and IL3, respectively. The rib layer 5 is provided on the organic insulating layer 12 and the lower electrodes LE1, LE2, and LE3. Each of the end portions (the end portions E1, E2, and E3 shown in FIG. 2) of the lower electrodes LE1, LE2, and LE3 and the end portions (the end portions E1x, E2x, and E3x shown in FIG. 2) of the inorganic insulating layers IL1, IL2, and IL3 is covered with the rib layer 5.

The partition 6 includes a conductive lower portion 61 provided on the rib layer 5 and an upper portion 62 provided on the lower portion 61. The upper portion 62 has a width greater than that of the lower portion 61. Accordingly, the both end portions of the upper portion 62 protrude relative to the side surfaces of the lower portion 61. In other words, the partition 6 has an overhang shape in which the both end portions of the upper portion 62 protrude relative to the side surfaces of the lower portion 61.

In the example of FIG. 3, the lower portion 61 includes a bottom layer 63 and a stem layer 64. The bottom layer 63 is located between the stem layer 64 and the rib layer 5. Furthermore, in the example of FIG. 3, the upper portion 62 includes a first top layer 65 and a second top layer 66. The first top layer 65 is provided on the stem layer 64. The second top layer 66 is provided on the first top layer 65.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the lower portions 61 of the partition 6.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2, and CP3 play a role of serving as optical adjustment layers which improve the extraction efficiency of the light emitted from the organic layers OR1, OR2, and OR3, respectively.

In the following descriptions, a multilayer body including the organic layer OR1, the upper electrode UE1, and the cap layer CP1 is referred to as a multilayer film FL1, a multilayer body including the organic layer OR2, the upper electrode UE2, and the cap layer CP2 is referred to as a multilayer film FL2, and a multilayer body including the organic layer OR3, the upper electrode UE3, and the cap layer CP3 is referred to as a multilayer film FL3.

Sealing layers SE11, SE12, and SE13 which cover the multilayer films FL1, FL2, and FL3, are provided in the subpixels SP1, SP2, and SP3, respectively. More specifically, the sealing layer SE11 continuously covers the cap layer CP1 and the partition 6 around the subpixel SP1. The sealing layer SE12 continuously covers the cap layer CP2 and the partition 6 around the subpixel SP2. The sealing layer SE13 continuously covers the cap layer CP3 and the partition 6 around the subpixel SP3.

In the example of FIG. 3, the sealing layer SE11 located on the partition 6 between the subpixels SP1 and SP2 is spaced apart from the sealing layer SE12 located on the partition 6. In addition, the sealing layer SE11 located on the partition 6 between the subpixels SP1 and SP3 is spaced apart from the sealing layer SE13 located on the partition 6. However, two of the sealing layers SE11, SE12, and SE13 may be in contact with each other above the partition 6.

For example, a gap is formed between each of the sealing layers SE11, SE12, and SE13 and the upper portion 62 of the partition 6. The multilayer films FL1, FL2, and FL3 may be provided in at least part of these gaps.

The sealing layers SE11, SE12, and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a protective film or a cover glass may be further provided above the resin layer RS2. Such a cover member may be attached to the resin layer RS2 via, for example, an adhesive layer such as an optical clear adhesive (OCA).

The electrodes which constitute the above-described touch panel may be provided on the sealing layer SE2. In addition, color filters corresponding to the colors of the subpixels SP1, SP2, and SP3 may be provided above the display elements DE1, DE2, and DE3, respectively.

The organic insulating layer 12 is formed of an organic insulating material such as polyimide. Each of the inorganic insulating layers IL1, IL2, and IL3, the rib layer 5, and the sealing layers SE11, SE12, SE13 and SE2 is formed of an inorganic insulating material such as silicon nitride (SiNx), silicon oxide (SiOx) or silicon oxynitride (SiON). For example, the inorganic insulating layers IL1, IL2, and IL3 are formed of silicon nitride, the rib layer 5 is formed of silicon oxynitride, and the sealing layers SE11, SE12, SE13, and SE2 are formed of silicon nitride. Each of the resin layers RS1 and RS2 is formed of, for example, a resinous material (organic insulating material) such as epoxy resin or acrylic resin.

Each of the upper electrodes UE1, UE2, and UE3 is formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 consists of a plurality of thin films including a light emitting layer. For example, each of the organic layers OR1, OR2, and OR3 comprises a structure in which a hole injection layer, a hole transport layer, an electron blocking layer, a light emitting layer, a hole blocking layer, an electron transport layer and an electron injection layer are stacked in order in a Z-direction. However, each of the organic layers OR1, OR2, and OR3 may have the other structure such as a so-called tandem structure including a plurality of light emitting layers.

Each of the cap layers CP1, CP2, and CP3 has, for example, a multilayer structure in which a plurality of transparent layers are stacked. These transparent layers may include a layer formed of an inorganic material and a layer formed of an organic material. In addition, the transparent layers have refractive indices different from each other. For example, the refractive indices of these transparent layers are different from the refractive indices of the upper electrodes UE1, UE2, and UE3 and the refractive indices of the sealing layers SE11, SE12, and SE13. Incidentally, at least one of the cap layers CP1, CP2, and CP3 may be omitted.

A common voltage is applied to the partition 6. This common voltage is applied to each of the upper electrodes UE1, UE2, and UE3 which are in contact with the lower portions 61. Pixel voltages corresponding to the video signals of the signal lines SL are applied to the lower electrodes LE1, LE2, and LE3 through the pixel circuits 1 of the subpixels SP1, SP2, and SP3, respectively.

The organic layers OR1, OR2, and OR3 emit light in accordance with the application of voltages. More specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light of the same color (for example, white). In this case, the display device DSP may comprise color filters which convert the light emitted from the light emitting layers into light of the colors corresponding to the subpixels SP1, SP2, and SP3. Alternatively, the display device DSP may comprise a layer including quantum dots which generate light of the colors corresponding to the subpixels SP1, SP2, and SP3 by the excitation caused by the light emitted from the light emitting layers.

Each of the bottom layer 63 and the stem layer 64 is formed of, for example, a metal material. For the metal material of the bottom layer 63, for example, molybdenum (Mo), titanium (Ti), titanium nitride (TiN), a molybdenum-tungsten alloy (MoW) or a molybdenum-niobium alloy (MoNb) can be used. For the metal material of the stem layer 64, for example, aluminum (Al), an aluminum-neodymium alloy (AlNd), an aluminum-yttrium alloy (AlY) or an aluminum-silicon alloy (AlSi) can be used. Incidentally, at least one of the bottom layer 63 and the stem layer 64 may have a multilayer structure consisting of a plurality of layers. In addition, the stem layer 64 may include a layer formed of an insulating material. Furthermore, the lower portion 61 may have a single-layer structure formed of a conductive material.

For example, the first top layer 65 is formed of a metal material, and the second top layer 66 is formed of a transparent conductive oxide. For the metal material of the first top layer 65, for example, titanium, titanium nitride, molybdenum, tungsten, a molybdenum-tungsten alloy or a molybdenum-niobium alloy can be used. For the conductive oxide of the second top layer 66, for example, indium tin oxide (ITO), indium zinc oxide (IZO), or indium gallium zinc oxide (IGZO) can be used. Incidentally, the upper portion 62 may have a single-layer structure formed of a specific material. Furthermore, the upper portion 62 may include a layer formed of an insulating material.

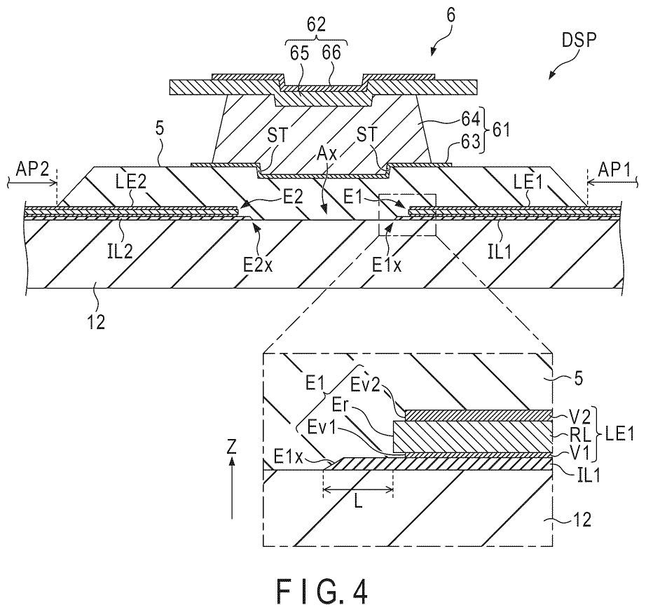

FIG. 4 is a schematic cross-sectional view showing the display device DSP along IV-IV line in FIG. 2. In this figure, the organic insulating layer 12, the rib layer 5, the partition 6, the inorganic insulating layers IL1 and IL2, and the lower electrodes LE1 and LE2 are shown, and the other elements are omitted.

In the example of FIG. 4, the bottom layer 63 protrudes from the side surfaces of the stem layer 64. In addition, the width of the second top layer 66 is smaller than the width of the first top layer 65. Accordingly, the upper surface of the first top layer 65 near the both end portions is exposed from the second top layer 66. The stem layer 64 is formed so as to be thicker than the bottom layer 63, the first top layer 65, and the second top layer 66.

As described above, the end portions E1x and E2x of the inorganic insulating layers IL1 and IL2 protrude from the end portions E1 and E2 of the lower electrodes LE1 and LE2, respectively. Each of the end portions E1, E2, E1x, and Ex2 is covered with the rib layer 5. Although not shown in the cross-section of FIG. 4, the end portion E3x of the inorganic insulating layer IL3 also protrudes from the end portion E3 of the lower electrode LE3. In addition, the end portions E3 and E3x are covered with the rib layer 5.

As shown in FIG. 2, each of the end portions E1 to E3 and E1x to E3x overlaps with the partition 6 in plan view along the entire periphery. As shown in FIG. 4, the end portions E1, E2, E1x, and E2x are located under the lower portion 61, more specifically, under the bottom layer 63 and the stem layer 64. Although not shown in the cross-section of FIG. 4, the end portion E3 of the lower electrode LE3 and the end portion E3x of the inorganic insulating layer IL3 are also located under the bottom layer 63 and the stem layer 64. However, each of the end portions E1 to E3 and E1x to E3x may have a portion which does not overlap with the bottom layer 63 or the stem layer 64 in plan view.

As shown in FIG. 4, stepped portions ST caused by the end portions E1 and E2 are generated on the upper surface of the rib layer 5. Although not shown in the cross-section of FIG. 4, a stepped portion ST caused by the end portion E3 of the lower electrode LE3 is generated on the upper surface of the rib layer 5. In the present embodiment, these stepped portions ST are covered with the bottom layer 63 and the stem layer 64. The upper surface of each of the stem layer 64, the first top layer 65, and the second top layer 66 may be deformed in accordance with the stepped portions ST.

As shown in the enlarged view of FIG. 4, the lower electrode LE1 includes a reflective layer RL, a first coating layer V1, and a second coating layer V2. The reflective layer RL reflects the light emitted from the organic layer OR1 in the Z-direction. The first coating layer V1 is located between the inorganic insulating layer IL1 and the reflective layer RL and covers the lower surface of the reflective layer RL. The second coating layer V2 covers the upper surface of the reflective layer RL. The first coating layer V1 improves the adherence between the reflective layer RL and the inorganic insulating layer IL1. The second coating layer V2 protects the reflective layer RL from various types of etching at the time of manufacturing the display device DSP.

The reflective layer RL can be formed of, for example, a metal material excellent in light reflectivity, such as silver. Each of the coating layers V1 and V2 can be formed of, for example, a transparent conductive oxide such as ITO, IZO or IGZO.

In the example of FIG. 4, each of the inorganic insulating layer IL1, the first coating layer V1, and the second coating layer V2 is thinner than the reflective layer RL. In addition, the first coating layer V1 is thinner than the inorganic insulating layer IL1 and the second coating layer V2. However, the relationship in thicknesses among the inorganic insulating layer IL1, the reflective layer RL, the first coating layer V1, and the second coating layer V2 is not limited to the example shown here.

In one example, the thickness of the reflective layer RL is 40 to 150 nm, the thickness of the first coating layer V1 is 5 to 10 nm, and the thickness of the second coating layer V2 is 5 to 50 nm. The thickness of the inorganic insulating layer IL1 is 10 to 50 nm. In addition, the thickness of the rib layer 5 is 200 to 600 nm. However, the thickness of the reflective layer RL, the first coating layer V1, the second coating layer V2, the inorganic insulating layer IL1, and the rib layer 5 is not limited to the example shown here.

The end portion E1 of the lower electrode LE1 includes the end portion Er of the reflective layer RL, the end portion Ev1 of the first coating layer V1, and the end portion Ev2 of the second coating layer V2. The end portion E1x of the inorganic insulating layer IL1 protrudes from each of the end portions Er, Ev1, and Ev2. The end portion E1x has, for example, a tapered shape in which the thickness gradually decreases. However, the end portion is not limited to this example. In the example of FIG. 4, the end portions Ev1 and Ev2 retreat relative to the end portion Er. A protrusion length L of the inorganic insulating layer IL1 from the reflective layer RL is, for example, greater than or equal to the thickness of the reflective layer RL. In one example, the protrusion length L is greater than or equal to 0.2 μm and, desirably, 0.5 μm to 1.0 μm.

Similarly to the lower electrode LE1, each of the lower electrodes LE2 and LE3 comprises the first coating layer V1 and the second coating layer V2. The thickness of the reflective layer RL, the first coating layer V1, and the second coating layer V2 in the lower electrodes LE2 and LE3 are equal to the thickness of these layers in the lower electrode LE1. The thickness of each of the inorganic insulating layers IL2 and IL3 is equal to the thickness of the inorganic insulating layer IL1. In addition, the structure of the vicinity of the end portion E2 of the lower electrode LE2 and the structure of the vicinity of the end portion E3 of the lower electrode LE3 are similar to the structure of the vicinity of the end portion E1 of the lower electrode LE1.

As shown in FIG. 4, the inorganic insulating layers IL1 and IL2 are separated from each other. Accordingly, an area Ax where the organic insulating layer 12 is exposed from the inorganic insulating layers IL1 and IL2 is formed between the end portions E1x and E2x. The area Ax overlaps with the lower portion 61 of the partition 6, more specifically, the bottom layer 63 and the stem layer 64 in plan view. In the area Ax, the organic insulating layer 12 is covered with the rib layer 5. A similar area Ax is also formed between the inorganic insulating layers IL1 and IL3 and between the inorganic insulating layer IL2 and IL3.

FIG. 5 is a schematic cross-sectional view showing the display device DSP along V-V line in FIG. 2. In this figure, the organic insulating layer 12, the rib layer 5, the partition 6, the inorganic insulating layers IL2 and IL3, and the lower electrodes LE2 and LE3 are shown, and the other elements are omitted.

A metal layer ML is provided under the contact hole CH2. The metal layer ML is a part of the circuit layer 11 and corresponds to a drain electrode of the drive transistor 3 in the pixel circuit 1 of the subpixel SP2.

In the example of FIG. 5, the inorganic insulating layer IL2 includes an aperture APx which overlaps with the contact hole CH2. A rim of the aperture APx is located on the organic insulating layer 12. In other words, the aperture APx entirely surrounds the contact hole CH2.

The lower electrode LE2 is in contact with the metal layer ML through the aperture APx and the contact hole CH2. The lower electrode LE2 entirely covers the inner surface of the contact hole CH2.

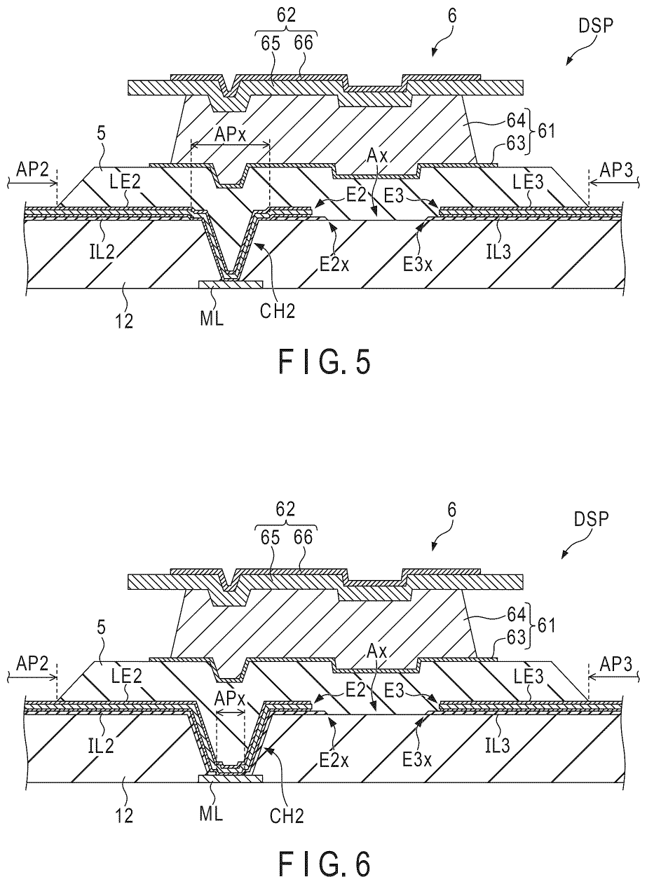

FIG. 6 is a schematic cross-sectional view showing another structure which can be applied to a vicinity of the contact hole CH2. In the example of this figure, the aperture APx is located inside the contact hole CH2. More specifically, the rim of the aperture APx is located on the metal layer ML. The inorganic insulating layer IL2 entirely covers the inner surface of the contact hole CH2.

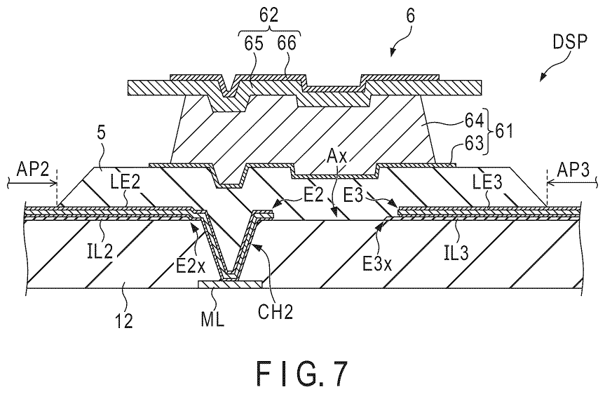

FIG. 7 is a schematic cross-sectional view showing yet another structure which can be applied to the vicinity of the contact hole CH2. In the example of this figure, the end portion E2x of the inorganic insulating layer IL2 is covered with the lower electrode LE2. Furthermore, the contact hole CH2 is located between the end portion E2x of the inorganic insulating layer IL2 and the end portion E2 of the lower electrode LE2.

For example, a relationship between the end portions E2 and E2x shown in FIG. 7 is applied to the only vicinity of the contact hole CH2. In other words, the end portion E2x includes a portion which protrudes from the lower electrode LE2 and a portion which is covered with the lower electrode LE2.

When the aperture APx is located outside the contact hole CH2 as shown in FIG. 5, the contact hole CH2 can be made smaller than that in the configuration in FIG. 6. In contrast, since the inner surface of the contact hole CH2 is covered with the inorganic insulating layer IL2 in the configuration of FIG. 6, impregnation of moisture from the inorganic insulating layer 12 can be desirably suppressed.

In the configuration of FIG. 7, since the aperture APx does not need to be provided in the inorganic insulating layer IL2, the structure in the vicinity of the contact hole CH2 is made simple. In addition, since the end portion E2x of the inorganic insulating layer IL2 does not protrude from the end portion E2 of the lower electrode LE2 in the vicinity of the contact hole CH2, margin between the inorganic insulating layer IL2 and IL3 can be made small and, consequently, the width of the rib layer 5 and the partition 6 can be made small. Accordingly, the aperture ratios of the subpixels SP1, SP2, and SP3 can be increased.

Incidentally, the inorganic insulating layer IL2 does not cover the inner surface of the contact hole CH2 in FIG. 5 and FIG. 7, while the inorganic insulating layer IL2 entirely covers the inner surface of the contact hole CH2 in FIG. 6. The inorganic insulating layer IL2 is not limited to these examples, but may cover a part of the inner surface of the contact hole CH2 and may not cover the other parts.

The relationship among the inorganic insulating layer IL2, the lower electrode LE2, and the contact hole CH2 shown in FIG. 5 to FIG. 7 can also be applied to the relationship among the inorganic insulating layer IL1, the lower electrode LE1, and the contact hole CH1, and the relationship among the inorganic insulating layer IL3, the lower electrode LE3, and the contact hole CH3.

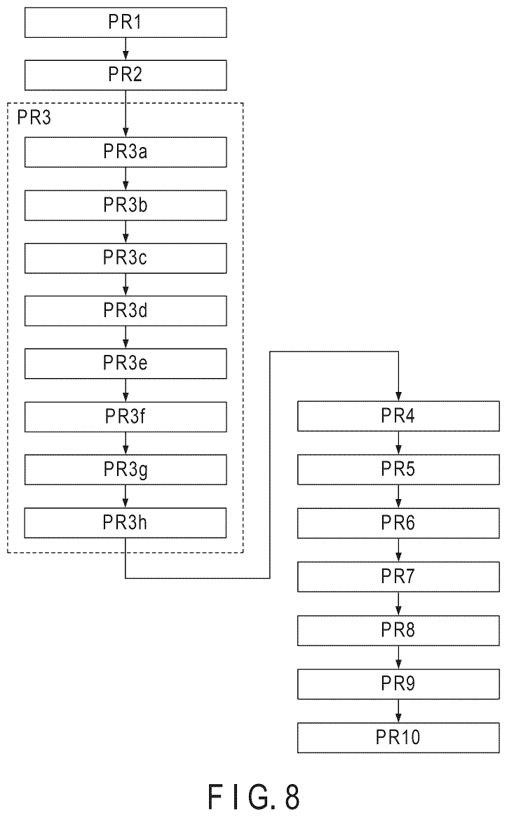

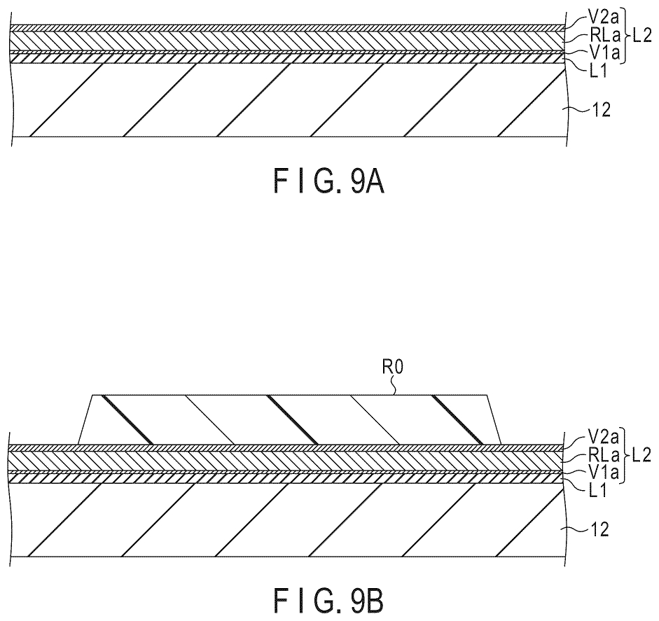

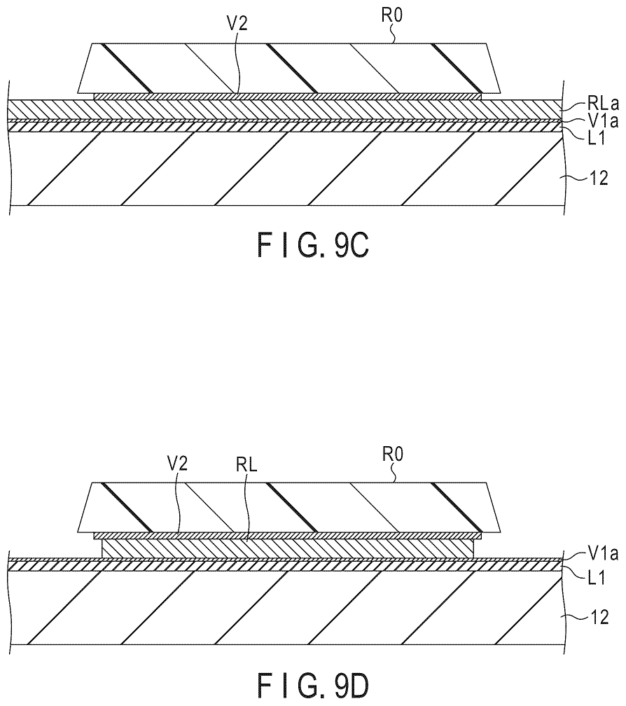

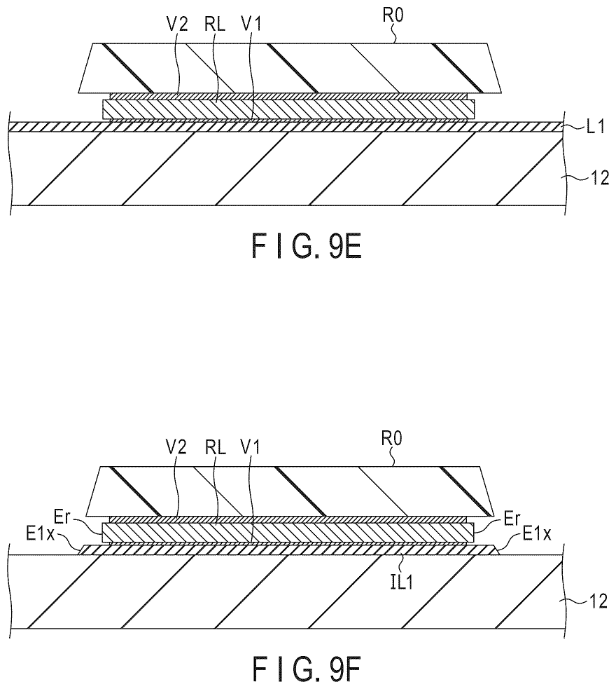

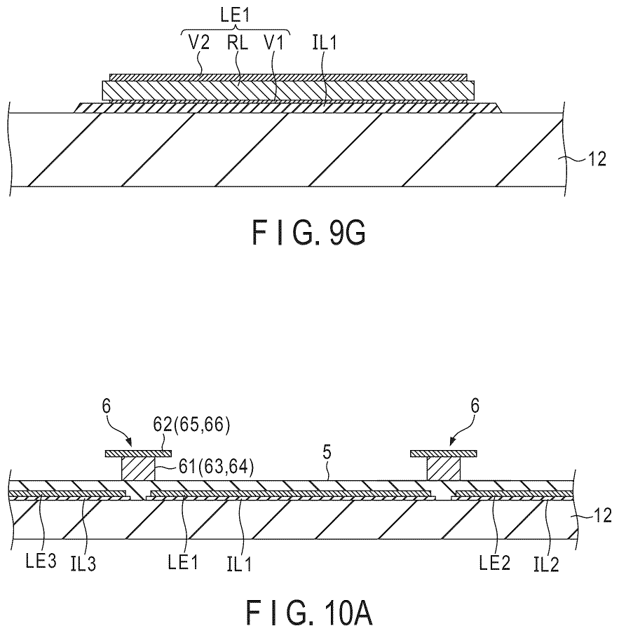

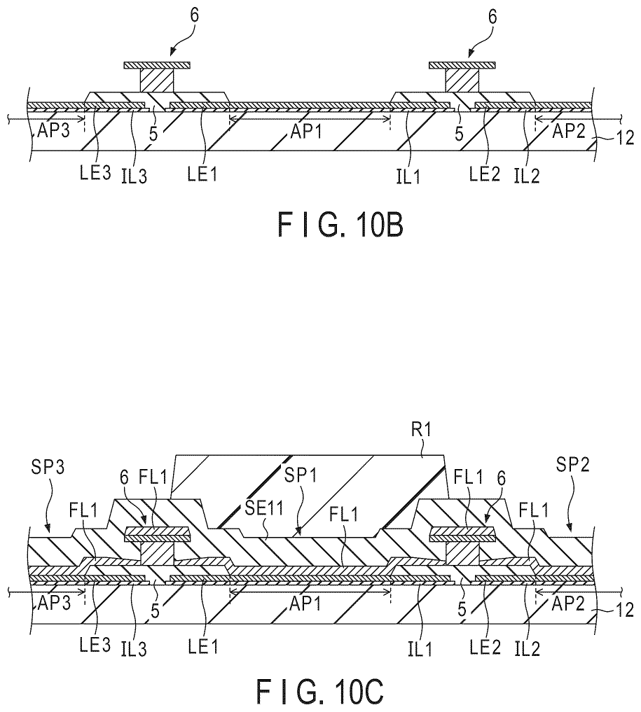

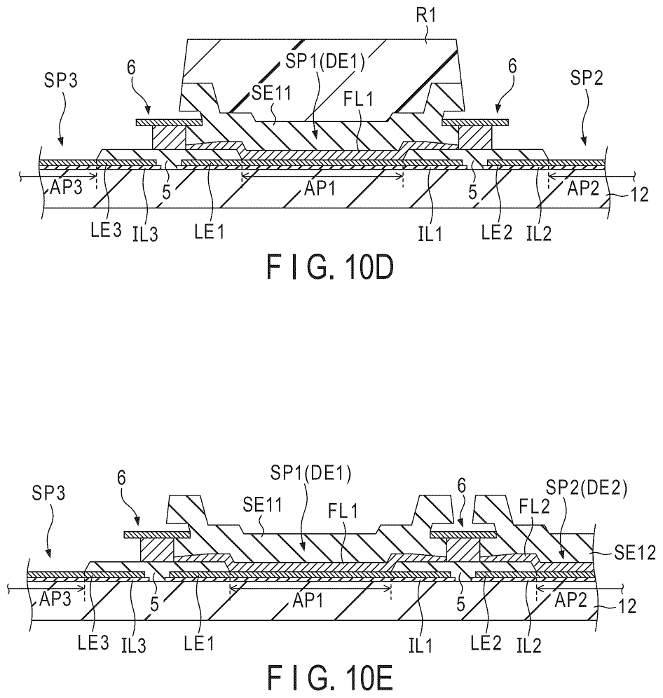

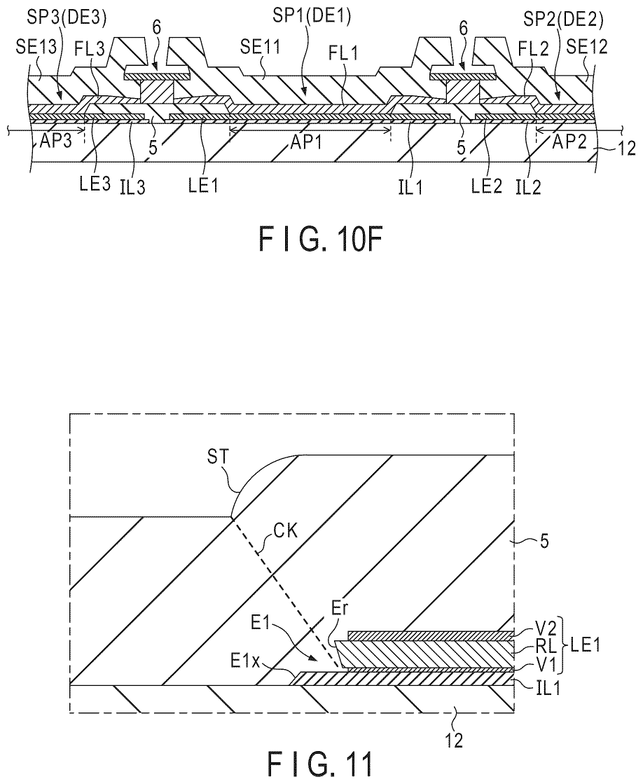

Next, an example of the method of manufacturing the display device DSP will be described. FIG. 8 is a flowchart showing an example of the method of manufacturing the display device DSP. Each of FIG. 9A to FIG. 9G and FIG. 10A to FIG. 10F is a schematic cross-sectional view showing the manufacturing process of the display device DSP. In these figures, illustration of the substrate 10 and the circuit layer 11 is omitted.

To manufacture the display device DSP, first, the circuit layer 11 is formed on the substrate 10 (process PR1 in FIG. 8). Furthermore, the organic insulating layer 12 which has the contact holes CH1, CH2 and CH3 is formed on the circuit layer 11 (process PR2 in FIG. 8).

After the process PR2, the inorganic insulating layers IL1, IL2, and IL3 and the lower electrodes LE1, LE2, and LE3 are formed on the organic insulating layer 12 (process PR3 in FIG. 8). The process PR3 is performed in, for example, a procedure shown in FIG. 9A to FIG. 9G. Incidentally, FIG. 9A to FIG. 9G show a situation in which the lower electrode LE1 and the inorganic insulating layer IL1 are formed. The lower electrodes LE2 and LE3 and the inorganic insulating layer IL2 and IL3 are also formed at the same time as the lower electrode LE1 and the inorganic insulating layer IL1.

In process PR3, first, as shown in FIG. 9A, a first layer L1 formed of the material of the inorganic insulating layers IL1, IL2, and IL3 is formed (process PR3a in FIG. 8). To form the first layer L1, for example, chemical vapor deposition (CVD) can be employed. Next, an aperture overlapping with each of the contact holes CH1, CH2, and CH3 is formed in the first layer L1 (process PR3b in FIG. 8). For example, when the configuration shown in FIG. 5 or FIG. 6 is applied, the aperture corresponds to the aperture APx. In addition, when the configuration shown in FIG. 7 is applied, the aperture is formed within a range including portions where the end portions E1, E2, and E3 of the lower electrodes LE1, LE2, and LE3 are to be located in the vicinity of the contact holes CH1, CH2, and CH3.

After the process PR3b, a second layer L2 formed of the material of the lower electrodes LE1, LE2, and LE3 is formed on the organic insulating layer 12 (process PR3c in FIG. 8). The second layer L2 includes a first coating layer V1a formed of the material of the first coating layer V1, a reflective layer RLa formed of the material of the reflective layer RL, and a second coating layer V2a formed of the material of the second coating layer V2. To form these layers, for example, sputtering can be employed.

Next, a resist R0 having a shape corresponding to the lower electrodes LE1, LE2, and LE3 is provided on the second coating layer V2a as shown in FIG. 9B (process PR3d in FIG. 8). Furthermore, first etching for the second layer L2 is performed (process PR3e in FIG. 8).

For example, the first etching includes wet etching performed for the second coating layer V2a, the reflective layer RLa, and the first coating layer V1a in order. In the wet etching for the second coating layer V2a, a portion of the second coating layer V2a, which is exposed from the resist R0, is removed. Accordingly, as shown in FIG. 9C, the second coating layer V2 is formed. In the example of FIG. 9C, the second coating layer V2 having a width which is slightly smaller than that of the resist R0 is formed.

In the wet etching for the reflective layer RLa, a portion of the reflective layer RLa, which is exposed from the resist R0, is removed. Accordingly, as shown in FIG. 9D, the reflective layer RL is formed. In addition, in the wet etching, the width of the reflective layer RL is slightly reduced relative to the width of the resist R0.

In the wet etching for the first coating layer V1a, a portion of the first coating layer V1a, which is exposed from the resist R0, is removed. Accordingly, as shown in FIG. 9E, the first coating layer VI is formed. In the example of FIG. 9E, the first coating layer V1 having a width which is slightly smaller than that of the reflective layer RL is formed. In addition, in the wet etching, the second coating layer V2 may also be corroded. Accordingly, in the example of FIG. 9E, the width of the second coating layer V2 is slightly reduced relative to the reflective layer RL.

After the first etching, second etching for the first layer L1 is performed (process PR3f in FIG. 8). In the second etching, a portion of the first layer L1, which is exposed from the resist R0, is removed. Accordingly, as shown in FIG. 9F, the inorganic insulating layer IL1 is formed.

The second etching is, for example, dry etching and is higher in anisotropy than each wet etching constituting the first etching. Therefore, the first layer L1 is patterned in a planar shape which is close to the resist R0 as compared to the reflective layer RL, the first coating layer V1, and the second coating layer V2. As a result, as shown in FIG. 9F, the end portion E1x of the inorganic insulating layer IL1 protrudes from the end portion Er of the reflective layer RL.

In addition, in the dry etching, the resist R0 is also slightly corroded. As a result, the width of the resist R0 is gradually reduced during the dry etching. Accordingly, the end portion E1x of the inorganic insulating layer IL1 is tapered. After the inorganic insulating layer IL1, the first coating layer V1, the reflective layer RL, and the second coating layer V2 are formed in this manner, the resist R0 is removed (peeled off) (process PR3g in FIG. 8).

After removing the resist R0, annealing treatment is performed for the first coating layer V1 and the second coating layer V2 that are formed of a conductive oxide (process PR3h in FIG. 8). In the annealing treatment, the first coating layer V1 and the second coating layer V2 are crystallized by heating. The lower electrode LE1 is completed as shown in FIG. 9G, in the above processes. The inorganic insulating layer IL2 and IL3 and the lower electrodes LE2 and LE3 are completed in the same manner.

Incidentally, the temperature of the organic insulating layer 12 is also raised in the above annealing treatment. Accordingly, moisture contained in the organic insulating layer 12 is evaporated through the area Ax between the inorganic insulating layers IL1, IL2, and IL3.

After the process PR3, as shown in FIG. 10A, the rib layer 5 which covers the lower electrodes LE1, LE2, and LE3 is formed (process PR4 in FIG. 8). Furthermore, the partition 6 having the lower portion 61 and the upper portion 62 is formed on the rib layer 5 (process PR5 in FIG. 8). The lower portion 61 includes the bottom layer 63 and the stem layer 64 as shown in FIG. 3. In addition, the upper portion 62 includes the first top layer 65 and the second top layer 66 as shown in FIG. 3. Incidentally, the structures of the lower electrodes LE1, LE2, and LE3 are simplified in FIG. 10A.

After the formation of the partition 6, as shown in FIG. 10B, the pixel apertures AP1, AP2, and AP3 are formed in the rib layer 5 (process PR6 in FIG. 8). As another example, the pixel apertures AP1, AP2, and AP3 may be formed before the formation of the partition 6.

Subsequently, a process for forming the display elements DE1, DE2, and DE3 is performed (processes PR7, PR8, and PR9 in FIG. 8). In the present embodiment, it is assumed that the display element DE1 is first formed, then the display element DE2 is formed, and the display element DE3 is formed lastly. However, the order of formation of the display elements DE1, DE2, and DE3 is not limited to this example.

To form the display element DE1, first, as shown in FIG. 10C, the multilayer film FL1 and the sealing layer SE11 are formed entirely for the display area DA and the surrounding area SA. The multilayer film FL1 includes, as shown in FIG. 3, the organic layer OR1 which is in contact with the lower electrode LE1 through the pixel aperture AP1, the upper electrode UE1 which covers the organic layer OR1, and the cap layer CP1 which covers the upper electrode UE1.

The organic layer OR1, the upper electrode UE1, and the cap layer CP1 are formed by vapor deposition. In addition, the sealing layer SE11 is formed by CVD. The multilayer film FL1 is divided into a plurality of portions by the partition 6 having an overhang shape. The sealing layer SE11 continuously covers each of the divided portions of the multilayer film FL1, and the partition 6.

After the formation of the multilayer film FL1 and the sealing layer SE11, as shown in FIG. 10C, the resist R1 is provided on the sealing layer SE11. The resist R1 covers the subpixel SP1 and part of the partition 6 around the subpixel.

After that, as shown in FIG. 10D, the portions of the multilayer film FL1 and the sealing layer SE11, which are exposed from the resist R1, are removed by etching using the resist R1 as a mask. Accordingly, the display element DE1 is formed in the subpixel SP1. For example, the etching includes wet etching and dry etching which are performed in order for the sealing layer SE11, the cap layer CP1, the upper electrode UE1, and the organic layer OR1. After these processes of etching, the resist R1 is removed.

The display elements DE2 and DE3 are formed in the same procedures as the display element DE1. In other words, to form the display element DE2, the multilayer film FL2 and the sealing layer SE12 are formed entirely for the display area DA and the surrounding area SA. The multilayer film FL2 includes, as shown in FIG. 3, the organic layer OR2 which is in contact with the lower electrode LE2 through the pixel aperture AP2, the upper electrode UE2 which covers the organic layer OR2, and the cap layer CP2 which covers the upper electrode UE2. By patterning the multilayer film FL2 and the sealing layer SE12, the display element DE2 is formed in the subpixel SP2 as shown in FIG. 10E.

In addition, to form the display element DE3, the multilayer film FL3 and the sealing layer SE13 are formed entirely for the display area DA and the surrounding area SA. The multilayer film FL3 includes, as shown in FIG. 3, the organic layer OR3 which is in contact with the lower electrode LE3 through the pixel aperture AP3, the upper electrode UE3 which covers the organic layer OR3, and the cap layer CP3 which covers the upper electrode UE3. By patterning the multilayer film FL3 and the sealing layer SE13, the display element DE3 is formed in the subpixel SP3 as shown in FIG. 10F.

After the display elements DE1, DE2, and DE3 are formed, the resin layer RS1, the sealing layer SE2, and the resin layer RS2 shown in FIG. 3 are formed in order (process PR10 in FIG. 8). The display device DSP is completed through these processes.

In the present embodiment described above, the display device DSP comprising the display elements DE1, DE2, and DE3 which are separated from each other for the respective subpixels SP1, SP2, and SP3 and which are individually sealed, by the partition 6 having an overhang shape, can be obtained.

In addition, according to the configuration of the inorganic insulating layers IL1, IL2, and IL3 and the lower electrodes LE1, LE2, and LE3 of the present embodiment, the yield and reliability of the display device DSP can be improved. These effects will be described below.

FIG. 11 is a diagram illustrating an example of effects obtained from the present embodiment, showing an example of the structure of the vicinity of the end portion E1 of the lower electrode LE1. To increase the reflectance of the lower electrode LE1, the reflective layer RL needs to be formed to be thick. In addition, the end portion Er of the reflective layer RL formed of a metal material such as silver and processed by wet etching is hardly tapered similarly to the end portion E1x of the inorganic insulating layer IL1. Therefore, the end portion Er can be formed in a sheer shape substantially parallel to the Z-direction as shown in FIG. 4 or an overhang shape in which the upper end protrudes as shown in FIG. 11.

Thus, in a case where the reflective layer RL is thick, the shape of the end portion Er is steep, and furthermore, the rib layer 5 is formed of an inorganic insulating material, a crack CK which extends from the vicinity of the end portion Er to the stepped portion ST of the upper surface of the rib layer 5 may occur. If the inorganic insulating layer IL1 is not provided under the lower electrode LE1, a moisture path from the organic insulating layer 12 to the upper surface of the rib layer 5 through the crack CK may be formed. If the moisture of the organic insulating layer 12 reaches the upper surface of the rib layer 5 through the moisture path, the organic layer OR1 provided on the rib layer 5, and the like, may be corroded, thereby causing a display failure.

In contrast, in the present embodiment, the inorganic insulating layer IL1 having the end portion E1x protruding from the reflective layer RL is provided. Accordingly, even if the crack CK occurs, the moisture path connecting the crack CK to the organic insulating layer 12 can be blocked by the inorganic insulating layer IL1. Furthermore, even if drawbacks such as partial disappearance and pinhole occur at the lower electrode LE1, impregnation of moisture from the organic insulating layer 12 to the multilayer film FL1 can be suppressed by providing the inorganic insulating layer IL1.

In addition, in the present embodiment, the inorganic insulating layer IL1 is formed so as to be thinner than the reflective layer RL. Furthermore, the end portion E1x of the inorganic insulating layer IL1 is tapered. Accordingly, occurrence of a crack CK caused by the end portion E1x is suppressed.

In addition, in the present embodiment, as shown in FIG. 4, the stepped portion ST of the upper surface of the rib layer 5 generated by the lower electrode LE1 is covered with the lower portion 61. In this case, the moisture path caused by the crack CK can also be blocked by the lower portion 61.

In addition, as shown in FIG. 9A to FIG. 9G, when the lower electrode LE1 and the inorganic insulating layer IL1 are patterned using a single resist R0, displacement therebetween can be suppressed.

The effects obtained from the present embodiment have been described by focusing the inorganic insulating layer IL1 and the lower electrode LE1. However, the same effects are also obtained from the inorganic insulating layers IL1 and IL2 and the lower electrodes LE2 and LE3.

### Second Embodiment

A second embodiment will be described. The configurations which are not particularly referred to in the present embodiment are the same as those of the first embodiment.

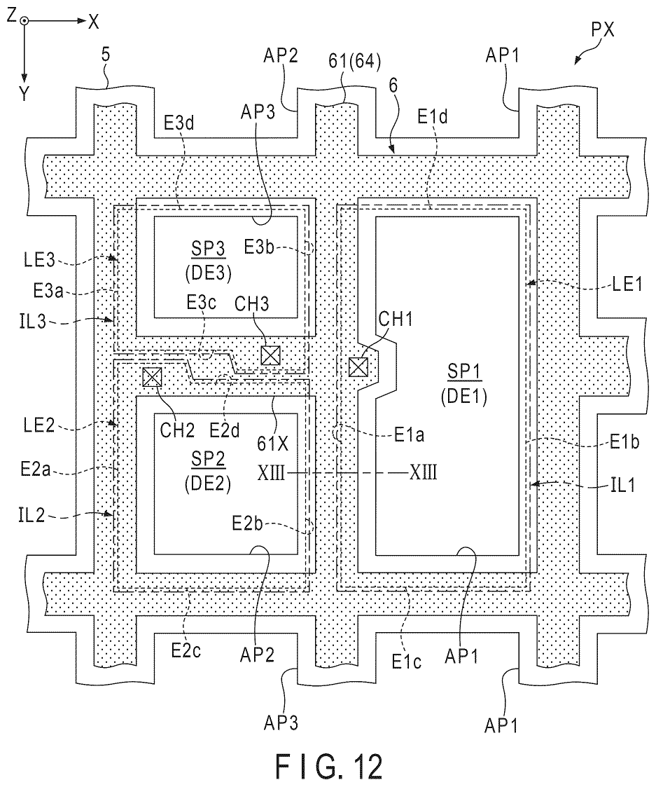

FIG. 12 is a schematic plan view showing an example of a layout of subpixels SP1, SP2, and SP3 according to the present embodiment. As shown in FIG. 12, a lower electrode LE1 has end portions E1a, E1b, E1c, and E1d. A lower electrode LE2 has end portions E2a, E2b, E2c, and E2d. A lower electrode LE3 has end portions E3a, E3b, E3c, and E3d. The end portions E1a, E1b, E2a, E2b, E3a, and E3b extend parallel to the Y-direction. In addition, the end portions E1c, E1d, E2c, E2d, E3c, and E3d extend parallel to the X-direction. Each of the end portions is covered with a rib layer 5.

The partition 6 shown in FIG. 12 corresponds to the shape of a lower portion 61, more specifically, the shape of a stem layer 64. In the present embodiment, a part (first end portion) of the end portion of each of the lower electrodes LE1, LE2, and LE3 overlaps with the stem layer 64, and the other part (second end portion) does not overlap with the stem layer 64. The expression that the end portion of each of the lower electrodes LE1, LE2, and LE3 overlaps with the lower portion 61 means that these end portions are located under the lower portion 61.

More specifically, the end portions E1a and E1c of the lower electrode LE1 overlap with the lower portion 61, and neither the end portion E1b nor the end portion E1d overlaps with the lower portion 61. In addition, the end portions E2a, E2c, and E2d of the lower electrode LE2 overlap with the lower portion 61, and the end portion E2b does not overlap with the lower portion 61. In addition, the end portions E3a and E3c of the lower electrode LE3 overlap with the lower portion 61, and neither the end portion E3b nor the end portion E3d overlaps with the lower portion 61.

For example, when the lower electrodes LE1 and LE2 and the lower portion 61 between them are focused, one of the end portions of each of the lower electrodes LE1 and LE2 overlaps with the lower portion 61, and the other end portion does not overlap with this lower portion 61. Thus, the relationship in which the lower portion 61 overlaps with one of the end portions of each of adjacent lower electrodes and does not overlap with the other end portion is established in a large part of the lower portion 61. However, the part 61X of the lower portion 61, which is located between the pixel apertures AP2 and AP3, overlaps with both the end portion E2d of the lower electrode LE2 and the end portion E3c of the lower electrode LE3. Contact holes CH2 and CH3 are provided under the portion 61X.

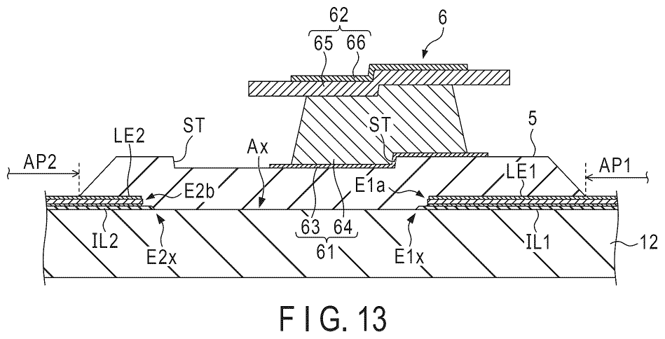

FIG. 13 is a schematic cross-sectional view showing the display device DSP along XIII-XIII line in FIG. 12. In this figure, similarly to FIG. 4, the organic insulating layer 12, the rib layer 5, the partition 6, the inorganic insulating layers IL1 and IL2, and the lower electrodes LE1 and LE2 are shown, and the other elements are omitted.

Similarly to the example of FIG. 4, an area Ax where the organic insulating layer 12 is exposed from the inorganic insulating layers IL1 and IL2 is formed between end portions E1x and E2x. In the example of FIG. 13, a part of the area Ax overlaps with the partition 6, and the other parts do not overlap with the partition 6.

A stepped portion ST generated on the upper surface of the rib layer 5 by an end portion located under the partition 6, such as the end portion E1a, is covered with a bottom layer 63 and the stem layer 64. In contrast, for example, a stepped portion ST generated by an end portion which is not located under the partition 6, such as the end portion E2b, is not covered with the bottom layer 63 or the stem layer 64.

In such a configuration, even if a crack occurs in the rib layer 5 by the stepped portion ST which is not covered with the partition 6, such as the stepped portion ST which is generated by the end portion E2b of the lower electrode LE2, moisture path caused by the crack cannot be blocked by the partition 6. However, by providing the inorganic insulating layers IL1, IL2, and IL3 under the lower electrodes LE1, LE2, and LE3, similarly to the first embodiment, the moisture path caused by the crack generated at the stepped portion ST can be blocked.

All of the display devices and manufacturing methods thereof that can be implemented by a person of ordinary skill in the art through arbitrary design changes to the display devices and manufacturing methods thereof disclosed above as each embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described above in the embodiments, which are obvious from the descriptions of the present specification or which can be arbitrarily conceived by a person of ordinary skill in the art, are considered to be achievable by the present invention as a matter of course.

What is claimed is:

1. A display device comprising:
an organic insulating layer formed of an organic insulating material;
a lower electrode provided above the organic insulating layer;
an inorganic insulating layer formed of an inorganic insulating material and provided between the organic insulating layer and the lower electrode;
a rib layer covering an end portion of the lower electrode and including a pixel aperture overlapping with the lower electrode;
an organic layer covering the lower electrode through the pixel aperture and emitting light in accordance with application of a voltage; and
an upper electrode covering the organic layer, wherein
an end portion of the inorganic insulating layer protrudes from an end portion of the lower electrode.

2. The display device of claim 1, wherein the end portion of the inorganic insulating layer is covered with the rib layer.

3. The display device of claim 1, further comprising:
a plurality of subpixels each including the lower electrode, the pixel aperture, the organic layer, the upper electrode, and the inorganic insulating layer, wherein
the inorganic insulating layers of the adjacent subpixels are separated from each other.

4. The display device of claim 3, wherein
the organic insulating layer is covered with the rib layer in an area between the adjacent inorganic insulating layers.

5. The display device of claim 4, further comprising:
a partition including a lower portion provided above the rib layer and an upper portion having an end portion protruding from a side surface of the lower portion, wherein
the area overlaps with the partition in plan view.

6. The display device of claim 5, wherein
the lower portion comprises:
a conductive bottom layer provided above the rib layer; and
a stem layer provided on the bottom layer, and
the area overlaps with the bottom layer in plan view.

7. The display device of claim 5, wherein
the plurality of subpixels include a first subpixel and a second subpixel that are adjacent to each other via the partition, and
both an end portion of the lower electrode of the first subpixel and an end portion of the lower electrode of the second subpixel overlap with the partition in plan view.

8. The display device of claim 5, wherein
the plurality of subpixels include a first subpixel and a second subpixel that are adjacent to each other via the partition, and
one of an end portion of the lower electrode of the first subpixel and an end portion of the lower electrode of the second subpixel overlaps with the partition and the other end portion does not overlap with the partition, in plan view.

9. The display device of claim 1, wherein
the organic insulating layer includes a contact hole overlapping with the lower electrode, and
the inorganic insulating layer includes an aperture overlapping with the contact hole.

10. The display device of claim 9, wherein
an edge of the aperture is located on the organic insulating layer.

11. The display device of claim 9, wherein
the inorganic insulating layer covers at least a part of an inner surface of the contact hole.

12. The display device of claim 9, wherein
a part of the end portion of the inorganic insulating layer is covered with the lower electrode, and
the contact hole is located between the part of the end portion of the inorganic insulating layer and the end portion of the lower electrode.

13. The display device of claim 1, wherein
the lower electrode comprises a reflective layer which reflects light emitted by the organic layer, and
the inorganic insulating layer is thinner than the reflective layer.

14. The display device of claim 13, wherein
the lower electrode further comprises a coating layer between the reflective layer and the inorganic insulating layer, and
the coating layer is formed of a transparent conductive oxide and formed to be thinner than the inorganic insulating layer.

15. A display device manufacturing method comprising:
forming an organic insulating layer of an organic insulating material;
forming above the organic insulating layer a lower electrode, and an inorganic insulating layer formed of an inorganic insulating material and located between the organic insulating layer and the lower electrode, the inorganic insulating layer having an end portion protruding from an end portion of the lower electrode;
forming a rib layer covering an end portion of the lower electrode and including a pixel aperture overlapping with the lower electrode;
forming an organic layer covering the lower electrode through the pixel aperture and emitting light in accordance with application of a voltage; and
forming an upper electrode covering the organic layer.

16. The display device manufacturing method of claim 15, wherein
the organic insulating layer includes a contact hole, and
the forming the lower electrode and the inorganic insulating layer includes:
forming a first layer of the inorganic insulating material above the organic insulating layer;
forming an aperture overlapping with the contact hole, in the first layer;
forming a second layer of the material of the lower electrode above the first layer;
forming the lower electrode by first etching for the second layer; and
forming the inorganic insulating layer by second etching for the first layer.

17. The display device manufacturing method of claim 15, wherein
the forming the lower electrode and the inorganic insulating layer includes:
forming a first layer of the inorganic insulating material above the organic insulating layer;
forming a second layer of the material of the lower electrode above the first layer;
providing a resist on the second layer;
forming the lower electrode by removing a portion of the second layer, which is exposed from the resist, by first etching; and
forming the inorganic insulating layer by removing a portion of the first layer, which is exposed from the resist, by second etching.

18. The display device manufacturing method of claim 17, wherein
a width of the second layer is reduced relative to a width of the resist by the first etching.

19. The display device manufacturing method of claim 16, wherein
the first etching is wet etching, and
the second etching is dry etching.

20. The display device manufacturing method of claim 15, further comprising:
forming a partition including a lower portion provided above the rib layer and an upper portion having an end portion protruding from a side surface of the lower portion, before forming the organic layer and the upper electrode.
